(19) United States
(12) Patent Application Publication
(10) Pub. No.: US 2017/0069748 A1
(43) Pub. Date: Mar. 9, 2017

(54) SEMICONDUCTOR DEVICE AND METHOD OF MANUFACTURING A SEMICONDUCTOR DEVICE

(71) Applicant: KABUSHIKI KAISHA TOSHIBA, Tokyo (JP)

(72) Inventor: Takeshi SHIBATA, Nonoichi Ishikawa (JP)

(21) Appl. No.: 15/062,211

(22) Filed: Mar. 7, 2016

(30) Foreign Application Priority Data
Sep. 9, 2015 (JP) 2015-177788

(51) Int. Cl. H01L 29/778; H01L 29/10; H01L 21/265; H01L 29/66

(52) U.S. Cl. CPC H01L 29/7787; H01L 29/66462; H01L 29/1095; H01L 21/26546

(57) ABSTRACT

A semiconductor device includes a substrate, a first layer above the substrate and including a nitride semiconductor layer, a second layer on the first layer, having first and second regions and including a nitride semiconductor layer containing Al, and an electrode on the first region. A peak concentration of an implanted material within the second layer in the first region is higher than a peak concentration of the implanted material within the second layer in the second region.

### CROSS-REFERENCE TO RELATED APPLICATION

This application is based upon and claims the benefit of priority from Japanese Patent Application No. 2015-177788, filed Sep. 9, 2015, the entire contents of which are incorporated herein by reference.

### FIELD

Embodiments described herein relate generally to a semiconductor device and a method of manufacturing the same.

### BACKGROUND

In gallium nitride-based semiconductor devices such as a high electron mobility transistor (GaN-HEMI), a metal such as an alloy of aluminum and titanium is used for a source electrode and a drain electrode. Such a metal electrode comes into ohmic contact with an AlGaN layer by heat treatment. However, since the quality of a gallium nitride-based material such as an AlGaN layer varies, there is a problem in that a contact resistance between the metal electrode and the AlGaN layer easily varies.

### DESCRIPTION OF THE DRAWINGS

FIG. 1 is a cross-sectional view illustrating an example of a configuration of a semiconductor device according to the present embodiment.

FIGS. 2A to 2C are graphs illustrating a profile of the concentration of a material implanted within an n type AlGaN layer of the semiconductor device.

FIGS. 3A to 3C are cross-sectional views illustrating steps of a method of manufacturing the semiconductor device according to the present embodiment.

FIGS. 4A and 4B are cross-sectional views illustrating further steps of a method of manufacturing the semiconductor device according to the present embodiment.

### DETAILED DESCRIPTION

Embodiments provide a semiconductor device and a method of manufacturing the semiconductor device which are capable of suppressing variations in a contact resistance between an electrode and a gallium nitride-based material.

In general, according to one embodiment, a semiconductor device includes a substrate, a first layer above the substrate and including a nitride semiconductor layer, a second layer on the first layer, having first and second regions and including a nitride semiconductor layer containing Al, and an electrode on the first region. A peak concentration of an implanted material within the second layer in the first region is higher than a peak concentration of the implanted material within the second layer in the second region.

Hereinafter, an embodiment will be described with reference to the accompanying drawings. The present embodiment does not limit the scope of the invention. In the following embodiment, a vertical direction of a semiconductor substrate indicates a relative direction when a surface having a semiconductor element provided thereon is set to face upward, and may be different from a vertical direction corresponding to the direction of gravitational acceleration.

In the present embodiment described below, gallium nitride (GaN) is used as a group III nitride semiconductor. However, instead of gallium nitride (GaN), aluminum nitride (AlN) or indium nitride (InN) may be used as a group III nitride semiconductor. Hereinafter, a group III nitride semiconductor will be described as being gallium nitride (GaN). In addition, in the present embodiment, for example, an AlGaN layer is used as a group III nitride semiconductor containing Al. The term “undoped” used herein means that the impurity concentration is 1×10¹⁵ cm⁻³ or less.

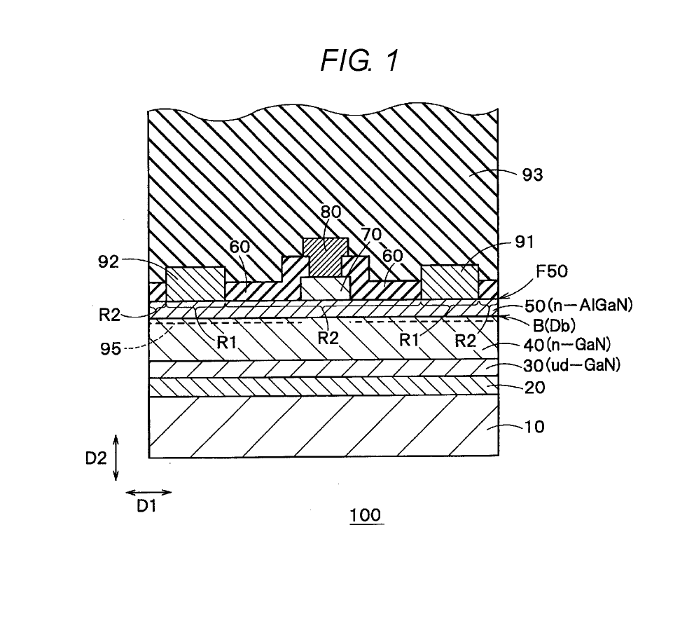

FIG. 1 is a cross-sectional view illustrating an example of a configuration of a semiconductor device 100 according to the present embodiment. The semiconductor device 100 includes a substrate 10, a buffer layer 20, an undoped GaN (ud-GaN) layer 30, an n type GaN layer 40, an n type AlGaN layer 50, an insulating film 60, a p type GaN layer 70, a metal gate electrode 80, a drain electrode 91, a source electrode 92, and an insulating interlayer film 93. For example, the semiconductor device 100 may be a junction field effect transistor (JFET) type GaN-HEMT illustrated in FIG. 1. However, the present embodiment is not limited to a JFET type, and may be any gallium nitride-based semiconductor device including an electrode requiring an ohmic contact. For example, the semiconductor device 100 may be a metal oxide semiconductor (MOS) FET type GaN-HEMI or the like. In addition, wirings, contacts, and the like which are provided within or on the insulating interlayer film 93 are not shown in the drawing.

The substrate 10 is a substrate containing any one or more of sapphire, diamond, SiC, GaN, BN, Si, and Ge. For example, the substrate may be a silicon substrate, a GaN substrate, a SiC substrate, or the like. The conductivity type of the substrate 10 is not particularly limited.

The buffer layer 20 is provided on a surface (first surface) of the substrate 10. The buffer layer 20 is formed to have, for example, a stacked structure of AlN and AlGaN. In addition, the buffer layer may be formed using a composition gradient AlGaN layer in which a content ratio of Al in AlGaN is gradually reduced toward the n type GaN layer 30 from the surface of the substrate 10. Warpage is suppressed by the buffer layer 20 interposed between the substrate 10 and a stacked structure (30, 40, and 50). In addition, the buffer layer 20 improves the crystallizability of the stacked structure including the GaN layers 30 and 40 and the AlGaN layer 50 provided thereon.

The ud-GaN layer 30 is provided on the buffer layer 20. The n type GaN layer 40 as a first layer, is provided on the ud-GaN layer 30. The n type GaN layer 40 is a GaN layer containing n type impurities (for example, silicon (Si) or germanium (Ge)).

The n type AlGaN layer 50 as a second layer, is provided on the n type GaN layer 40. The n type AlGaN layer 50 is an AlGaN layer containing n type impurities (for example, silicon (Si) or germanium (Ge)). The n type AlGaN layer 50 includes a first region R1 and a second region R2. In addition, the AlGaN layer 50 is not necessarily an n type, and may be a p type or intrinsic.

The n type GaN layer 40 and the n type AlGaN layer 50 form a heterostructure, and thus a two-dimensional electron gas (hereinafter, also referred to as 2DEG) layer 95 is generated at an interface between the n type GaN layer 40 and the n type AlGaN layer 50. The 2DEG layer 95 functions to reduce an electric resistance between the drain electrode 91 and the source electrode 92 and to reduce an on-resistance of the semiconductor device 100.

The p type GaN layer 70 as a third layer, is provided on the second region R2 in the n type AlGaN layer 50. The p type GaN layer 70 is a GaN layer containing p type impurities (for example, magnesium (Mg)). The second region R2 is a region other than the first region R1 (contact region), having the drain electrode 91 and the source electrode 92 provided therein, in the n type AlGaN layer 50. In addition, the p type GaN layer 70 functions as a portion of a gate electrode.

The metal gate electrode 80 is provided on the p type GaN layer 70. For example, a conductive metal material such as aluminum (Al), tantalum (Ta), tantalum nitride (TaN), titanium (Ti), or titanium nitride (TiN) is used for the metal gate electrode 80.

The insulating film 60 is provided on the second region R2 of the n type AlGaN layer 50 and on the side surface of the p type GaN layer 70. The insulating film 60 is an insulating film such as SiO₂, SiN, Al₂O₃, or ZrO.

The drain electrode 91 and the source electrode 92 are provided on the first region R1 of the n type AlGaN layer 50. The drain electrode 91 and the source electrode 92 come into ohmic contact with the n type AlGaN layer 50. The same material as that of the metal gate electrode 80 maybe used for the drain electrode 91 and the source electrode 92. For example, a conductive metal material such as aluminum (Al), tantalum (Ta), tantalum nitride (TaN), titanium (Ti), or titanium nitride (TiN) is used for the drain electrode 91 and the source electrode 92. In the present embodiment, an alloy of aluminum and titanium is used for the drain electrode 91 and the source electrode 92.

Here, the concentration of a first material (for example, aluminum or other impurities) within the n type AlGaN layer 50 will be described. In general, the n type AlGaN layer 50 is formed through epitaxial growth while introducing aluminum or n type impurities (for example, silicon (Si) or germanium (Ge)) by a metal organic chemical vapor deposition (MOCVD) method. In this case, the concentration of aluminum or impurities contained in the n type AlGaN layer 50 is substantially uniform within a plane (direction D1) of an upper surface F50 of the n type AlGaN layer 50, and hardly varies between the first region R1 and the second region R2.

On the other hand, in the present embodiment, as described later, a first material is selectively ion-implanted into the n type AlGaN layer 50 in the first region R1 using a lithography technique and an ion implantation technique. The first material may be any of, for example, aluminum (Al), silicon (Si), gallium (Ga), germanium (Ge), nitrogen (N), fluorine (F), oxygen (O), carbon (C), indium (In), antimony (Sb), boron (B), phosphorus (P), and arsenic (As). In addition, the first material maybe a material causing a crystal defect in the n type AlGaN layer 50. Therefore, the first material maybe a material capable of being ion-implanted, and is not particularly limited. However, a material that exerts adverse influences on the 2DEG layer, element characteristics, and the like by being ion-implanted into the n type AlGaN layer 50 is not preferable.

As a result of the first material being injected into the first region R1, the concentration of the first material contained in the n type AlGaN layer 50 in the first region R1 becomes higher than the concentration of the first material contained in the n type AlGaN layer 50 in the second region R2. That is, the concentration of the first material contained in the n type AlGaN layer 50 under the drain electrode 91 and the source electrode 92 is relatively high, and the concentration of the first material contained in the n type AlGaN layer 50 in the second region R2 is relatively low.

In addition, the first material is injected into a position shallower than a boundary (2DEG layer 95) between the n type GaN layer 40 and the n type AlGaN layer 50, during the ion implantation. Therefore, the concentration of the first material has a maximum value (peak) within the n type AlGaN layer 50 in the first region R1 in a stack direction D2 (that is, a depth direction) of the n type GaN layer 40 and the n type AlGaN layer 50. That is, a profile of the concentration of the first material in the depth direction has a maximum value (peak) on the side closer to the source electrode 92 or the drain electrode 91 than the boundary between the n type GaN layer 40 and the n type AlGaN layer 50. In other words, a maximum value of the concentration of the first material is located at a position (shallow position) which is closer to the side of the drain electrode 91 or the source electrode 92 than the 2DEG layer 95.

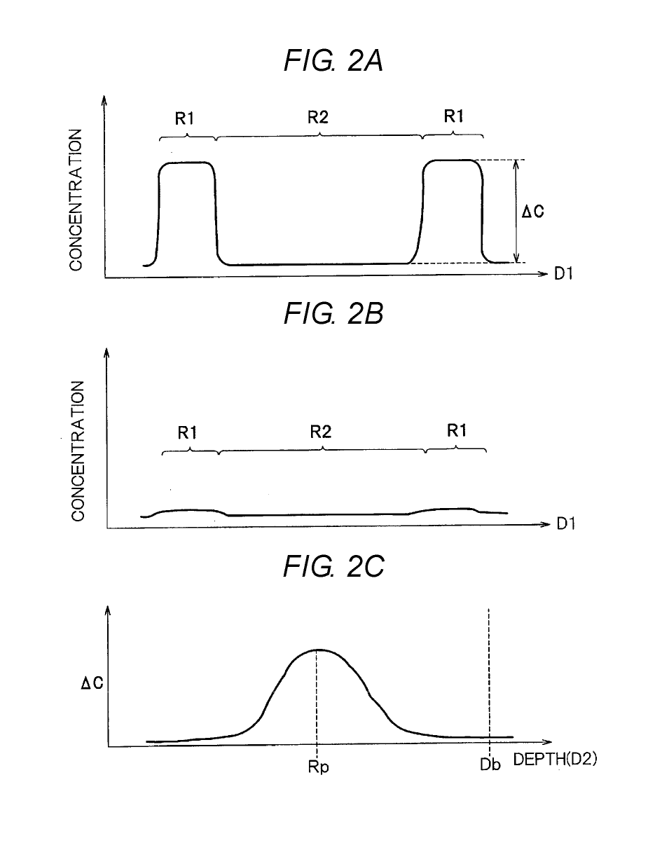

For example, FIG. 2A is a graph illustrating a profile of the concentration of a first material in a certain ion implantation depth (Rp) within the n type AlGaN layer 50. A vertical axis represents the concentration of the first material, and a horizontal axis represents a distance in the direction D1 for a certain ion implantation depth (Rp) within the AlGaN layer 50. As described above, the first material is selectively injected into the first region R1, and thus the concentration of the first material in the first region R1 becomes higher than that in the second region R2.

FIG. 2B is a graph illustrating a profile of the concentration of a first material at a boundary B (depth Db) between the n type AlGaN layer 50 and the n type GaN layer 40. A vertical axis represents the concentration of the first material, and a horizontal axis represents a distance in the direction D1 at the boundary B. The first material is injected into a position shallower than the boundary (2DEG layer 95) between the n type GaN layer 40 and the n type AlGaN layer 50 during ion implantation. For this reason, the concentration of the first material decreases at the boundary B relative to the depth Rp.

FIG. 2C is a graph illustrating a difference ΔC in the concentration of a first material between a first region R1 and a second region R2 in a depth direction D2. A vertical axis represents a difference ΔC in the concentration of the first material between the first region R1 and the second region R2. A horizontal axis represents a depth in a direction D2. Referring to FIG. 2C, a maximum value of the difference ΔC in the concentration of the first material is located at the position of a depth Rp, and is located within the n type AlGaN layer 50. That is, the position is shallower than a depth Db of a boundary (2DEG layer 95) between the n type AlGaN layer 50 and the n type GaN layer 40.

A profile of the concentration of the first material is substantially the same as a profile of the density of a crystal defect. Therefore, it can be said that the density of a crystal defect within the n type AlGaN layer 50 in the first region R1 is higher than the density of a crystal defect within the n type AlGaN layer 50 in the second region R2. In addition, a difference in the density of a crystal defect within the n type AlGaN layer 50 between the first region R1 and the second region R2 has a maximum value within the n type AlGaN layer 50 in the direction D2 (depth direction). That is, the maximum value of a difference in the density of a crystal defect between the first region R1 and the second region R2 is located closer to the source electrode 92 side or the drain electrode 91 side than the boundary B (2DEG layer 95) between the n type GaN layer 40 and the n type AlGaN layer 50. This is because a defect occurs in the n type AlGaN layer 50 in the first region R1 by the ion implantation of the first material.

In this manner, in the semiconductor device 100 according to the present embodiment, the concentration of the first material or the density of a crystal defect is higher within the n type AlGaN layer 50 in the first region R1 than that in the second region R2. In addition, a profile of the concentration of the first material in the direction D2 (depth direction) or a profile of the density of a crystal defect has a maximum value at a position shallower than that at the boundary B (2DEG layer 95) of FIG. 1. Further, a difference in the concentration of the first material in the direction D2 or a difference in the density of a crystal defect has a maximum value at a position shallower than that at the boundary B (2DEG layer 95).

When a great amount of first material or crystal defect is included in the n type AlGaN layer 50, there is a tendency for nitrogen to be extracted from the n type AlGaN layer 50 and for the metal (for example, aluminum) of the drain electrode 91 and the source electrode 92 to enter the n type AlGaN layer 50 during ohmic annealing after the drain electrode 91 and the source electrode 92 are formed. That is, the crystal defect formed within the n type AlGaN layer 50 in the first region R1 functions as a movement path for nitrogen and aluminum. Through this movement path, nitrogen is extracted from the n type AlGaN layer 50, while the metal of the drain electrode 91 and the source electrode 92 tends to enter the n type AlGaN layer 50. Thereby, the drain electrode 91 and the source electrode 92 can come into ohmic contact with the n type AlGaN layer 50 in the first region R1 stably and with low resistance.

In addition, the metal of the drain electrode 91 and the source electrode 92 may include a metal with a high reducibility. For example, titanium has a relatively high reducibility, and thus can reduce an oxide film or the like by heat treatment. Therefore, when the drain electrode 91 and the source electrode 92 are an alloy of aluminum and titanium, it is possible to reduce a natural oxide film or the like formed on the upper surface of the n type AlGaN layer 50 during ohmic annealing and to remove an oxide film from a contact surface in the first region R1. Thereby, it is possible to easily bring the drain electrode 91 and the source electrode 92 into contact with the n type AlGaN layer 50.

In addition, titanium included in the drain electrode 91 and the source electrode 92 can prevent aluminum from dissolving due to a liquid chemical that is applied during a cleaning process, a developing process of a lithography technique, or the like.

Next, a method of manufacturing the semiconductor device 100 according to the present embodiment will be described.

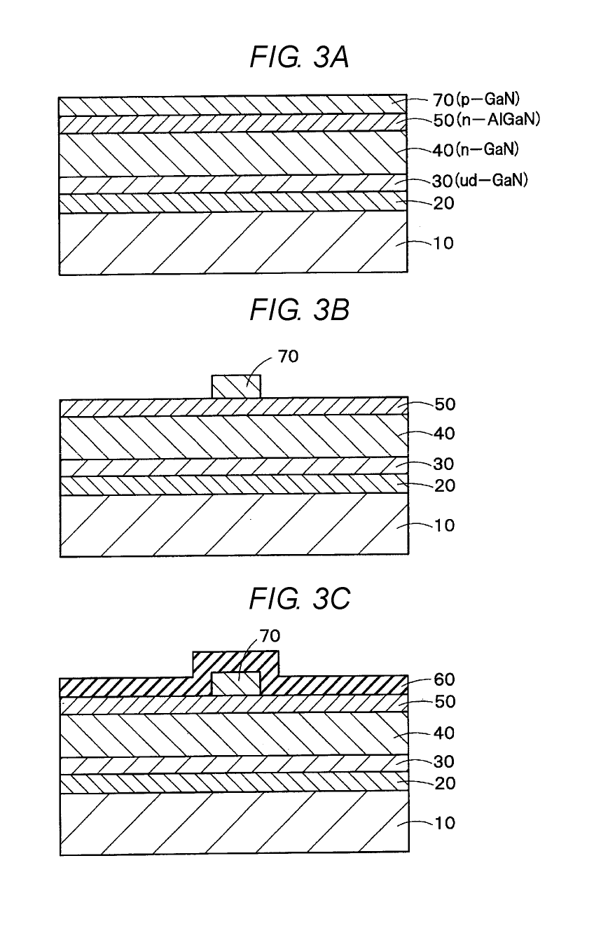

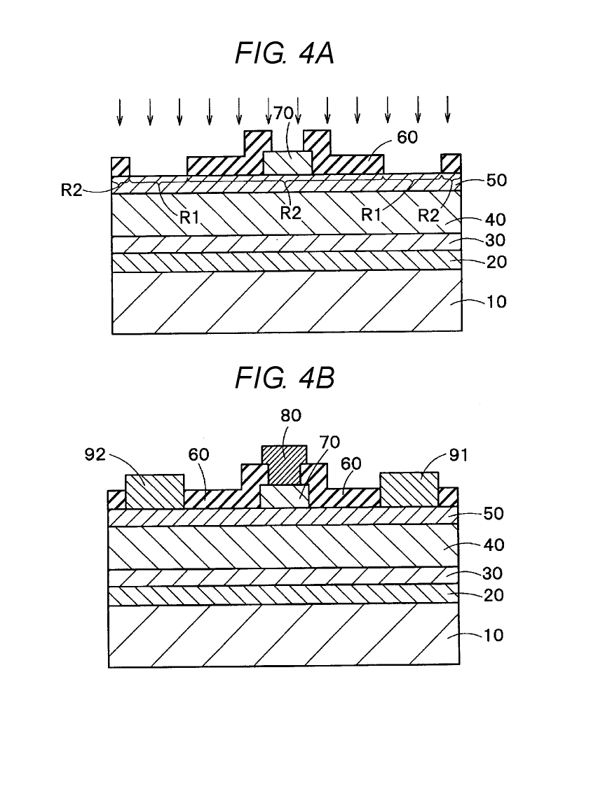

FIG. 3A to FIG. 4B are cross-sectional views illustrating steps of a method of manufacturing the semiconductor device 100 according to the present embodiment. The method of manufacturing the semiconductor device 100 will be described with reference to FIG. 3A to FIG. 4B.

First, the buffer layer 20 is formed on the substrate 10 by a metal organic chemical vapor deposition (MOCVD) method. As described above, the buffer layer 20 includes a stacked structure of AlN and AlGaN, or a composition gradient AlGaN layer. For example, when the stacked structure of AlN and AlGaN is formed on the substrate 10, an AlN layer and an AlGaN layer may be alternately stacked on the substrate 10. For example, when the composition gradient AlGaN layer is formed on the substrate 10, first, the content of Al in AlGaN is set to 100%, and AlGaN is deposited while gradually decreasing the content of Al. In addition, the content of Al in the uppermost portion of the buffer layer 20 may be set to 0%.

Next, the ud-GaN layer 30 is deposited on the buffer layer 20 using a MOCVD method. At this time, GaN is deposited without adding impurities.

Next, the n type GaN layer 40 is deposited using a MOCVD method. At this time, GaN is deposited while adding n type impurities (for example, Si or Ge).

Next, the n type AlGaN layer 50 is deposited on the n type GaN layer 40 using a MOCVD method. At this time, GaN is deposited while adding n type impurities (for example, Si or Ge) and Al.

Next, the p type GaN layer 70 is deposited on the n type AlGaN layer 50 using a MOCVD method. At this time, the epitaxial growth of GaN is performed while adding p type impurities (for example, magnesium). In addition, the epitaxial growth of the buffer layer 20, the ud-GaN layer 30, the n type GaN layer 40, the n type AlGaN layer 50, and the p type GaN layer 70 may be consecutively performed in the same MOCVD device.

Next, the p type GaN layer 70 is processed into a pattern of a gate electrode as illustrated in FIG. 3B using a lithography technique and an etching technique.

Next, the insulating film 60 as a mask material is deposited on the n type AlGaN layer 50. The insulating film 60 is an insulating film such as SiO₂, SiN, Al₂O₃, or ZrO, but is not limited thereto. Thereby, a stacked structure illustrated in FIG. 3C is obtained.

Next, the insulating film 60 located in a gate electrode formation region, a source electrode formation region, and a drain electrode formation region is removed using a lithography technique and an etching technique.

Next, as illustrated in FIG. 4A, the first material is ion-implanted by an ion implantation technique using the insulating film 60 as a mask. As described above, the first material may be any of, for example, aluminum (Al), silicon (Si), gallium (Ga), germanium (Ge), nitrogen (N), fluorine (F), oxygen (O), carbon (C), indium (In), antimony (Sb), boron (B), phosphorus (P), and arsenic (As).

The first material is selectively injected into the n type AlGaN layer 50 in the first region R1 (source electrode formation region and drain electrode formation region) by the ion implantation. The n type AlGaN layer 50 in the second region R2 is shielded by the insulating film 60, and thus the first material is not injected into the n type AlGaN layer 50 in the second region R2. In addition, the ion implantation is performed with energy for making the first material stay within the n type AlGaN layer 50. Thereby, the concentration of the first material is higher in the n type AlGaN layer 50 in the first region R1 than in the n type AlGaN layer 50 in the second region R2, and has a maximum value within the n type AlGaN layer 50 in the first region R1 in a depth direction. In addition, a maximum value of a difference ΔC in the concentration of the first material between the first region R1 and the second region R2 in the depth direction D2 is located at the position of a depth Rp shallower than a depth Db and is located within the n type AlGaN layer 50. Accordingly, the density of a crystal defect is higher in the n type AlGaN layer 50 in the first region R1 than in the n type AlGaN layer 50 in the second region R2, and has a maximum value within the n type AlGaN layer 50 in the first region R1 in the depth direction. In addition, a difference in the density of the crystal defect between the first region R1 and the second region R2 in the depth direction D2 is located at the position of a depth Rp shallower than a depth Db and is located within the n type AlGaN layer 50.

Next, a metal material is deposited on the p type GaN layer 70 in the gate electrode formation region and on the n type AlGaN layer 50 in the source electrode formation region and the drain electrode formation region. The metal material is a conductive metal material such as Ta, TaN, Ti, or TiN. In the present embodiment, the metal material is titanium and aluminum.

Next, the metal material is processed using a lithography technique and an etching technique. Thereby, the metal gate electrode 80 is formed on the p type GaN layer 70, the drain electrode 91 is formed in the source electrode formation region, and the source electrode 92 is formed in the source electrode formation region.

Next, ohmic annealing is performed. For example, the ohmic annealing is performed at a temperature of approximately 800° C. to 900° C. by a rapid thermal annealing (RTA) method. Thereby, a contact portion between the drain electrode 91 and the n type AlGaN layer 50, a contact portion between the source electrode 92 and the n type AlGaN layer 50, and a contact portion between the gate electrode 80 and the p type GaN layer 70 each become an ohmic contact portion.

Here, in the n type AlGaN layer 50 in the first region R1 which includes a great amount of first material or crystal defect, a great amount of nitrogen is extracted from the n type AlGaN layer, and a great amount of metal (for example, aluminum) of the drain electrode 91 and the source electrode 92 enters the n type AlGaN layer. That is, there is a tendency for the nitrogen to be extracted from the n type AlGaN layer 50 and for the metal of the drain electrode 91 and the source electrode 92 to enter the n type AlGaN layer 50 as a result of the crystal defect formed by the ion implantation of the first material. In this manner, the first material is selectively injected into the n type AlGaN layer 50 in the first region R1, and thus the drain electrode 91 and the source electrode 92 can come into ohmic contact with then type AlGaN layer 50 in the first region R1 with low resistance during ohmic annealing.

The first material is selectively ion-implanted into the n type AlGaN layer 50 in the first region R1, and thus a crystal defect is formed in the n type AlGaN layer 50 in the first region R1 to be substantially uniform on purpose. Therefore, the drain electrode 91 and the source electrode 92 can stably come into ohmic contact with the n type AlGaN layer 50 in the first region R1. That is, according to the present embodiment, it is possible not only to reduce the contact resistance between the drain electrode 91 and the source electrode 92 and but also to suppress variations in the contact resistance therebetween.

Thereafter, the manufacture of the semiconductor device 100 illustrated in FIG. 1 is completed by forming the insulating interlayer film 93, contacts, and wirings (not illustrated).

In this manner, according to the present embodiment, a first material is selectively ion-implanted into the n type AlGaN layer 50 in the first region R1 (drain electrode formation region and source electrode formation region). Accordingly, the density of a crystal defect within the n type AlGaN layer 50 in the first region R1 is increased. Thereby, based on the tendency for nitrogen to be extracted from the n type AlGaN layer 50 and for the metal (for example, aluminum) of the drain electrode 91 and the source electrode 92 to enter the n type AlGaN layer 50 during ohmic annealing after the drain electrode 91 and the source electrode 92 are formed, the drain electrode 91 and the source electrode 92 can come into ohmic contact with the n type AlGaN layer 50 in the first region R1 with low resistance and stably.

In addition, when the drain electrode 91 and the source electrode 92 include a metal (for example, titanium) with a high reducibility, it is possible to reduce a natural oxide film or the like formed on the upper surface of the n type AlGaN layer 50 during ohmic annealing and to remove an oxide film from a contact surface in the first region R1. Thereby, it is possible to easily bring the drain electrode 91 and the source electrode 92 into contact with the n type AlGaN layer 50.

In addition, titanium included in the drain electrode 91 and the source electrode 92 can prevent aluminum from dissolving due to a liquid chemical that is applied during a cleaning process, a developing process of a lithography technique, or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first layer above the substrate and including a nitride semiconductor layer;
a second layer on the first layer, having first and second regions and including a nitride semiconductor layer containing Al; and
an electrode on the first region,
wherein a peak concentration of an implanted material within the second layer in the first region is higher than a peak concentration of the implanted material within the second layer in the second region.

2. The device according to claim 1, wherein the peak concentration of the implanted material within the second layer in the first region is at a location closer to a side of the electrode than a side of the first layer.

3. The device according to claim 1, wherein the implanted material is any one of aluminum (Al), silicon (Si), gallium (Ga), germanium (Ge), nitrogen (N), fluorine (F), oxygen (O), carbon (C), indium (In), antimony (Sb), boron (B), phosphorus (P), and arsenic (As).

4. The device according to claim 1,
wherein a density of a crystal defect in the first region is higher than a density of a crystal defect in the second region.

5. The device according to claim 5, wherein the electrode is in ohmic contact with the second layer.

6. A semiconductor device comprising:
a substrate;
a first layer above the substrate and including a group III nitride semiconductor layer;
a second layer having first and second regions on the first layer, having first and second regions and including a nitride semiconductor layer containing Al; and
an electrode on the first region,
wherein a density of a crystal defect within the second layer in the first region is higher than a density of a crystal defect within the second layer in the second region.

7. The device according to claim 6, wherein a peak local density of the crystal defects within the second layer in the first region is at location closer to a side of the electrode than a side of the first layer.

8. The device according to claim 6, wherein the implanted material is any one of aluminum (Al), silicon (Si), gallium (Ga), germanium (Ge), nitrogen (N), fluorine (F), oxygen (O), carbon (C), indium (In), antimony (Sb), boron (B), phosphorus (P), and arsenic (As).

9. The device according to claim 6, wherein the source electrode and the drain electrode are in ohmic contact with the second layer.

10. A method of manufacturing a semiconductor device, the method comprising:
forming a first layer that includes a nitride semiconductor layer, above a substrate;
forming a second layer that includes a nitride semiconductor layer containing Al and has first and second regions, on the first layer;
selectively injecting a material into the first region of the second layer while masking the second region of the second layer; and
forming an electrode on the first region of the second layer.

11. The method according to claim 12, further comprising:
performing annealing to form an ohmic contact between the electrode and the second layer.

12. The method according to claim 10, wherein a peak concentration of an injected material within the second layer in the first region is higher than a peak concentration of the implanted material within the second layer in the second region.

13. The method according to claim 12, wherein the peak concentration of the injected material within the second layer in the first region is at a location closer to a side of the electrode than a side of the first layer.

14. The method according to claim 10, wherein the injected material is any one of aluminum (Al), silicon (Si), gallium (Ga), germanium (Ge), nitrogen (N), fluorine (F), oxygen (O), carbon (C), indium (In), antimony (Sb), boron (B), phosphorus (P), and arsenic (As).

15. The method according to claim 10, wherein a density of a crystal defect in the first region is higher than a density of a crystal defect in the second region

16. The device according to claim 15, wherein a peak local density of the crystal defects within the second layer in the first region is at location closer to a side of the electrode than a side of the first layer.
